(19) United States
(12) Patent Application Publication
(10) Pub. No.: US 2026/0158947 A1
(43) Pub. Date: Jun. 11, 2026

(54) DRIVE DEVICE

(71) Applicant: TOYOTA JIDOSHA KABUSHIKI KAISHA, Toyota-shi (JP)

(72) Inventors: Yuki HAYAKAWA, Toyota-shi (JP); Takeru TANAKA, Toyota-shi (JP)

(73) Assignee: TOYOTA JIDOSHA KABUSHIKI KAISHA, Toyota-shi (JP)

(21) Appl. No.: 19/396,463

(22) Filed: Nov. 21, 2025

(30) Foreign Application Priority Data
Dec. 11, 2024 (JP) 2024-216216

(51) Int. Cl. B60L 53/24; B60L 3/00; G01R 31/327; G01R 31/40; H02J 7/34; H02M 7/797

(52) U.S. Cl. CPC B60L 53/24; B60L 3/0092; G01R 31/3278; G01R 31/40; H02J 7/345; H02M 7/797; B60L 2210/12; B60L 2210/30; B60L 2210/42; H02J 2207/50

(57) ABSTRACT

In a normal state, the system startup is performed by turning on the positive-side relay of the system main relay and the precharge relay to charge the high-voltage-side smoothing capacitor, then turning on the negative-side relay, and further charging the branch-side smoothing capacitor by the DC/DC converter before turning on the branch relay. When an abnormality occurs in the DC/DC converter, the system startup is performed by turning on the positive-side relay of the system main relay and the branch relay, and turning on the precharge relay to charge the high-voltage-side smoothing capacitor and the branch-side smoothing capacitor, and then turning on the negative-side relay.

### CROSS-REFERENCE TO RELATED APPLICATION

The present disclosure claims priority to Japanese Patent Application No. 2024-216216 filed on Dec. 11, 2024, which is incorporated herein by reference in its entirety including specification, drawings and claims.

### TECHNICAL FIELD

This disclosure relates to a drive device, and more particularly to a drive device including an open-winding motor, a first inverter connected to one end of a three-phase coil of the open-winding motor, and a second inverter connected to the other end of the three-phase coil of the open-winding motor.

### BACKGROUND

Conventionally, as a drive device of this type, a configuration has been proposed that includes an open-winding motor, a first inverter connected to one end of a three-phase coil of the open-winding motor, and a second inverter connected to the other end of the three-phase coil of the open-winding motor (see, for example, Patent Document 1). In this drive device, a first battery and a second battery are provided, and by switching between individual charging of one of the first battery and the second battery, and simultaneous charging of both the first battery and the second battery, the two batteries can be appropriately charged.

### CITATION LIST

### Patent Literature

PTL 1: JPA 2020-096520

### SUMMARY

In the above-described drive device, it is common to provide a system main relay, a plurality of relays for switching between individual charging and simultaneous charging, and a DC/DC converter that exchanges power with voltage conversion between a high-voltage power line for driving and a low-voltage power line for auxiliary equipment. In such a case, system startup is normally performed with precharging of a smoothing capacitor by the system main relay and the DC/DC converter. However, when an abnormality occurs in either the system main relay or the DC/DC converter, there may arise a situation in which precharging of the smoothing capacitor cannot be carried out.

An object of the present disclosure is to provide a drive device that is capable of performing system startup with precharging of a smoothing capacitor even when an abnormality occurs in either the system main relay or the DC/DC converter.

In order to achieve the above-described primary object, the drive device of the present disclosure employs the following configuration.

According to a first aspect of the present disclosure, there is provided a drive device comprising:
a power storage device;
an open-winding motor;
a first inverter connected to a high-voltage power line connected to the power storage device and to one end of a three-phase coil of the open-winding motor;
a second inverter connected to the high-voltage power line and to the other end of the three-phase coil of the open-winding motor;
a high-voltage-side smoothing capacitor mounted on the high-voltage power line;
a system main relay comprising a positive-side relay mounted on a positive line of the high-voltage power line on a side of the power storage device relative to the smoothing capacitor, a negative-side relay mounted on a negative line of the high-voltage power line, and a precharge circuit formed by a precharge relay connected in parallel with the negative-side relay and a limiting resistor connected in series with the precharge relay;
an auxiliary battery;
a DC/DC converter connected to a branch power line connected between the positive line of the high-voltage power line between the power storage device and the system main relay and the negative line of the high-voltage power line between the system main relay and the first inverter, and further connected to a low-voltage power line connected to the auxiliary battery, the DC/DC converter being configured to exchange power with voltage conversion between the branch power line and the low-voltage power line;
a branch relay mounted on the branch power line;
a branch-side smoothing capacitor mounted on the branch power line between the branch relay and the DC/DC converter; and
a controller configured to control the first inverter, the second inverter, and the DC/DC converter, and to drive-control the system main relay and the branch relay,
wherein the controller is configured to:
in a normal condition, turn on the positive-side relay of the system main relay and the precharge relay to charge the high-voltage-side smoothing capacitor, then turn on the negative-side relay, and further charge the branch-side smoothing capacitor by the DC/DC converter and then turn on the branch relay to start the system; and
when an abnormality occurs in the DC/DC converter, turn on the positive-side relay of the system main relay and the branch relay, and also turn on the precharge relay to charge the high-voltage-side smoothing capacitor and the branch-side smoothing capacitor, and then turn on the negative-side relay to start the system.

In the first drive device of the present disclosure, in a normal condition, the positive-side relay and the precharge relay of the system main relay mounted on the high-voltage power line connected to the power storage device are turned on to charge the high-voltage-side smoothing capacitor mounted on the high-voltage power line on the first inverter side of the system main relay, then the negative-side relay is turned on, and thereafter the DC/DC converter, which is connected to a branch power line connected between the positive line between the power storage device and the system main relay and the negative line between the system main relay and the first inverter, and also connected to a low-voltage power line connected to the auxiliary battery, charges the branch-side smoothing capacitor mounted on the branch power line, and then the branch relay is turned on to start the system. On the other hand, when an abnormality occurs in the DC/DC converter, the positive-side relay of the system main relay and the branch relay are turned on, and the precharge relay is also turned on to charge the high-voltage-side smoothing capacitor and the branch-side smoothing capacitor, then the negative-side relay is turned on to start the system. Accordingly, even when an abnormality occurs in the DC/DC converter, system startup can be performed with precharging of the high-voltage-side smoothing capacitor and the branch-side smoothing capacitor.

Here, in a normal condition, in more detail, the positive-side relay is first turned on, then the precharge relay is turned on to charge the high-voltage-side smoothing capacitor, after completion of charging of the high-voltage-side smoothing capacitor the negative-side relay is turned on and then the precharge relay is turned off, thereafter the branch-side smoothing capacitor is charged by the DC/DC converter, and then the branch relay is turned on to start the system. When an abnormality occurs in the DC/DC converter, in more detail, the positive-side relay and the branch relay are first turned on, then the precharge relay is turned on to charge the high-voltage-side smoothing capacitor and the branch-side smoothing capacitor, after completion of charging of the high-voltage-side smoothing capacitor and the branch-side smoothing capacitor the negative-side relay is turned on and then the precharge relay is turned off, and the system is thereby started.

A second drive device according to the present disclosure comprises:
a power storage device;
an open-winding motor;
a first inverter connected to a high-voltage power line connected to the power storage device and to one end of a three-phase coil of the open-winding motor;
a second inverter connected to the high-voltage power line and to the other end of the three-phase coil of the open-winding motor;
a high-voltage-side smoothing capacitor mounted on the high-voltage power line;
a system main relay comprising a positive-side relay mounted on a positive line of the high-voltage power line on a side of the power storage device relative to the smoothing capacitor, a negative-side relay mounted on a negative line of the high-voltage power line, and a precharge circuit formed by a precharge relay connected in parallel with the negative-side relay and a limiting resistor connected in series with the precharge relay;
an auxiliary battery;
a DC/DC converter connected to a branch power line connected between the positive line of the high-voltage power line between the power storage device and the system main relay and the negative line of the high-voltage power line between the system main relay and the first inverter, and further connected to a low-voltage power line connected to the auxiliary battery, the DC/DC converter being configured to exchange power with voltage conversion between the branch power line and the low-voltage power line;
a branch relay mounted on the branch power line;
a branch-side smoothing capacitor mounted on the branch power line between the branch relay and the DC/DC converter; and
a controller configured to control the first inverter, the second inverter, and the DC/DC converter, and to drive-control the system main relay and the branch relay,
wherein the controller is configured to:
in a normal condition, turn on the positive-side relay of the system main relay and the precharge relay to charge the high-voltage-side smoothing capacitor, then turn on the negative-side relay, and further charge the branch-side smoothing capacitor by the DC/DC converter and then turn on the branch relay to start the system; and
when an abnormality occurs in the precharge relay, turn on the positive-side relay of the system main relay and the branch relay, and further charge the high-voltage-side smoothing capacitor and the branch-side smoothing capacitor by the DC/DC converter, then turn on the negative-side relay to start the system.

In the second drive device of the present disclosure, in a normal condition, the positive-side relay and the precharge relay of the system main relay mounted on the high-voltage power line connected to the power storage device are turned on to charge the high-voltage-side smoothing capacitor mounted on the high-voltage power line on the first inverter side of the system main relay, then the negative-side relay is turned on, and thereafter the DC/DC converter, which is connected to a branch power line connected between the positive line between the power storage device and the system main relay and the negative line between the system main relay and the first inverter, and also connected to a low-voltage power line connected to the auxiliary battery, charges the branch-side smoothing capacitor mounted on the branch power line, and then the branch relay is turned on to start the system. On the other hand, when an abnormality occurs in the precharge relay, the positive-side relay of the system main relay and the branch relay are turned on, and the DC/DC converter charges the high-voltage-side smoothing capacitor and the branch-side smoothing capacitor, then the negative-side relay is turned on to start the system. Accordingly, even when an abnormality occurs in the precharge relay of the system main relay, system startup can be performed with precharging of the high-voltage-side smoothing capacitor and the branch-side smoothing capacitor.

Here, in a normal condition, in more detail, the positive-side relay is first turned on, then the precharge relay is turned on to charge the high-voltage-side smoothing capacitor, after completion of charging of the high-voltage-side smoothing capacitor the negative-side relay is turned on and then the precharge relay is turned off, thereafter the branch-side smoothing capacitor is charged by the DC/DC converter, and then the branch relay is turned on to start the system. On the other hand, when an abnormality occurs in the precharge relay, in more detail, the positive-side relay and the branch relay are first turned on, then the DC/DC converter charges the high-voltage-side smoothing capacitor and the branch-side smoothing capacitor, after completion of charging of the high-voltage-side smoothing capacitor and the branch-side smoothing capacitor the negative-side relay is turned on to start the system.

### BRIEF DESCRIPTION OF DRAWINGS

FIG. 1 is a configuration diagram illustrating an outline of the structure of a drive device according to one embodiment of the present disclosure.

FIG. 2 is a flowchart illustrating an example of a system startup process executed by an electronic control unit.

FIG. 3 is a flowchart illustrating an example of a startup process when an abnormality occurs in the DC/DC converter.

FIG. 4 is a flowchart illustrating an example of a startup process when an abnormality occurs in the SMRP.

FIG. 5 is an explanatory diagram illustrating an example of a system startup sequence when both the DC/DC converter and the precharge relay SMRP are determined to be normal.

FIG. 6 is an explanatory diagram illustrating an example of a system startup sequence when an abnormality is determined to have occurred in the DC/DC converter.

FIG. 7 is an explanatory diagram illustrating an example of a system startup sequence when an abnormality is determined to have occurred in the precharge relay SMRP.

### DESCRIPTION OF EMBODIMENTS

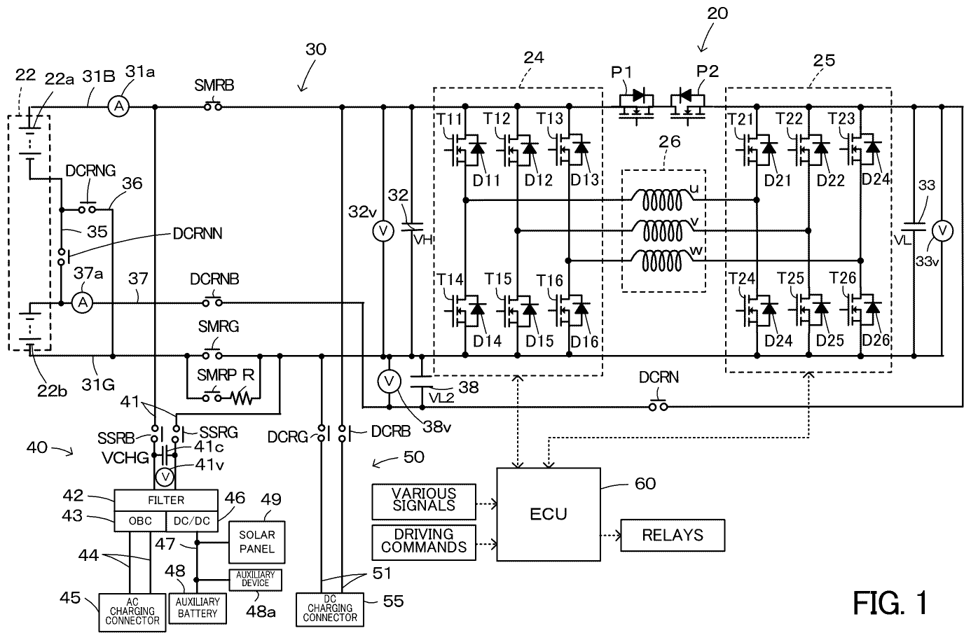

Next, embodiments for carrying out the present disclosure will be described. FIG. 1 is a configuration diagram illustrating an outline of the structure of the drive device 20 according to one embodiment of the present disclosure. The drive device 20 of the embodiment comprises the battery 22, the first inverter 24, the second inverter 25, the open-winding motor 26, the main power circuit 30, the AC charging circuit 40, the DC charging circuit 50, and the electronic control unit (ECU) 60.

The battery 22 includes the first battery 22a and the second battery 22b configured in the same manner as the first battery 22a. The first battery 22a and the second battery 22b are, for example, configured as lithium-ion secondary batteries or nickel-metal hydride secondary batteries. The positive terminal of the first battery 22a is connected to the positive-side power line 31B, and the negative terminal of the second battery 22b is connected to the negative-side power line 31G. The negative terminal of the first battery 22a is connected to the positive terminal of the second battery 22b by a series power line 35 on which a relay DCRNN, included in the configuration of the main power circuit 30, is mounted. Accordingly, by turning on the relay DCRNN, the first battery 22a and the second battery 22b function as a single battery connected in series.

The first inverter 24 is connected to the positive-side power line 31B and the negative-side power line 31G to which the battery 22 is connected, and includes six transistors T11 to T16 serving as switching elements, and six diodes D11 to D16 each connected in parallel with a corresponding one of the transistors T11 to T16. The transistors T11 to T16 are all formed of SiC-MOSFETs (SiC-Metal Oxide Semiconductor Field Effect Transistors). Among the transistors T11 to T16, pairs of two transistors (the transistor T11 and the transistor T14, the transistor T12 and the transistor T15, and the transistor T13 and the transistor T16) are arranged such that they serve as a source side and a sink side with respect to the positive-side power line 31B and the negative-side power line 31G. Further, each connection point of the paired transistors T11 to T16 is connected to one end of each of the three-phase coils (u-phase, v-phase, and w-phase coils) of the open-winding motor 26.

The second inverter 25 is connected to the positive-side power line 31B and the negative-side power line 31G to which the battery 22 is connected, such that the battery 22 and the first inverter 24 are interposed therebetween, and includes six transistors T21 to T26 serving as switching elements, and six diodes D21 to D26 each connected in parallel with a corresponding one of the transistors T21 to T26. The transistors T21 to T26 of the second inverter 25 are configured, similarly to the transistors T11 to T16 of the first inverter 24, as SiC-MOSFETs. Among the transistors T21 to T26, pairs of two transistors (the transistor T21 and the transistor T24, the transistor T22 and the transistor T25, and the transistor T23 and the transistor T26) are arranged such that they serve as a source side and a sink side with respect to the positive-side power line 31B and the negative-side power line 31G. Further, each connection point of the paired transistors T21 to T26 is connected to the other end of each of the three-phase coils (u-phase, v-phase, and w-phase coils) of the open-winding motor 26.

The connection switches P1 and P2 are mounted on the positive-side power line 31B between the first inverter 24 and the second inverter 25. The connection switches P1 and P2 are configured, similarly to the transistors T11 to T16 of the first inverter 24 and the transistors T21 to T26 of the second inverter 25, as SiC-MOSFETs.

The open-winding motor 26 is a generator motor in which both ends of each of the three-phase windings of the u-phase, v-phase, and w-phase are configured as connection terminals. Three connection points of the paired transistors of the first inverter 24 are connected to one end of the three-phase windings of the u-phase, v-phase, and w-phase, and three connection points of the paired transistors of the second inverter 25 are connected to the other ends of the three-phase windings of the u-phase, v-phase, and w-phase.

In the drive device 20 of the embodiment, the open-winding motor 26 can be driven in a star connection by turning off the connection switches P1 and P2, turning on the upper-arm transistors T21 to T23 of the second inverter 25 while turning off the lower-arm transistors T24 to T26, and performing switching control of the transistors T11 to T16 of the first inverter 24. That is, by turning off the connection switches P1 and P2 and turning on the upper-arm transistors T21 to T23 of the second inverter 25, the u-phase, v-phase, and w-phase of the open-winding motor 26 are brought to a neutral point by the transistors T21 to T23 that are turned on, and the open-winding motor 26 is driven by the first inverter 24 as a star-connected motor. On the other hand, the open-winding motor 26 can be driven in a delta connection by turning on the connection switches P1 and P2, and performing switching control of the transistors T11 to T16 of the first inverter 24 together with switching control of the transistors T21 to T26 of the second inverter 25.

The main power circuit 30 includes, in addition to the positive-side power line 31B, the negative-side power line 31G, and the series power line 35, a first parallel power line 36 connecting the negative terminal of the first battery 22a and the negative-side power line 31G, and a second parallel power line 37 connecting the positive terminal of the second battery 22b to the positive-side power line 31B of the second inverter 25 (a neutral point during star connection driving). The positive-side power line 31B is provided with the positive-side relay SMRB, and the negative-side power line 31G is provided with the negative-side relay SMRG. Further, the negative-side power line 31G is provided with a precharge circuit including a precharge relay SMRP and a resistor R, connected in parallel with the negative-side relay SMRG. The positive-side relay SMRB, the negative-side relay SMRG, and the precharge circuit constitute the system main relay. Between the first inverter 24 and the system main relay on the positive-side power line 31B and the negative-side power line 31G, the first smoothing capacitor 32 is mounted, and on the side of the second inverter 25 of the positive-side power line 31B and the negative-side power line 31G, the second smoothing capacitor 33 is mounted.

The first parallel power line 36 is provided with the relay DCRNG. The second parallel power line 37 is provided with the relay DCRNB on the side of the second battery 22b, and the relay DCRN on the side of the positive-side power line 31B of the second inverter 25 (a neutral point during star connection driving). Between the relay DCRNB and the relay DCRN of the second parallel power line 37 and the negative-side power line 31G, the third smoothing capacitor 38 is mounted.

The AC charging circuit 40 includes an AC charging power line 41 connected between the positive terminal of the battery 22 and the relay SMRB on the positive-side power line 31B, and between the relay SMRG and the first inverter 24 on the negative-side power line 31G. The AC charging circuit 40 further includes an on-board charger (OBC) 43 connected to the AC charging power line 41 via a filter 42, an AC charging connector 45 connected to the on-board charger 43 via a power line 44, a DC/DC converter 46 connected in parallel with the on-board charger 43 to the AC charging power line 41 via the filter 42, an auxiliary battery 48 and an auxiliary device 48a connected to the DC/DC converter 46 via a power line 47, and a solar panel 49.

The DC charging circuit 50 includes a DC charging power line 51 connected to the positive-side power line 31B and the negative-side power line 31G, and a DC charging connector 55 connected to the DC charging power line 51. The positive line of the DC charging power line 51 is provided with the relay DCRB, and the negative line is provided with the relay DCRG.

The electronic control unit 60 is configured as a microcomputer centering on a CPU, although not shown. Various signals from sensors are input to the electronic control unit 60. Examples of such sensors include: a voltage sensor 32v for detecting a voltage VH between terminals of the first smoothing capacitor 32; a voltage sensor 33v for detecting a voltage VL between terminals of the second smoothing capacitor 33; a voltage sensor 38v for detecting a voltage VL2 between terminals of the third smoothing capacitor 38; a voltage sensor 31v for detecting a voltage VCHG between terminals of the AC charging smoothing capacitor 41c; a current sensor 31a for detecting a current Ib1 flowing through the first battery 22a; a current sensor 37a for detecting a current Id flowing through the second parallel power line 37; a phase current sensor (not shown) for detecting phase currents Iu, Iv, and Iw flowing through the three phases of the open-winding motor 26; a voltage sensor (not shown) for detecting a voltage Vb1 between terminals of the first battery 22a; and a voltage sensor (not shown) for detecting a voltage Vb2 between terminals of the second battery 22b. The electronic control unit 60 also functions as a controller for driving the open-winding motor 26, and therefore receives driving commands and the like. Further, when the drive device 20 is mounted on a vehicle and the open-winding motor 26 is used as a traveling motor, The electronic control unit 60 may receive inputs such as an accelerator opening degree and a vehicle speed, and generate a torque command for the open-winding motor 26.

The electronic control unit (ECU) 60 outputs drive control signals to the respective relays, switching control signals to the first inverter 24 and the second inverter 25, and drive signals to the connection switches P1 and P2. Examples of the relays include the positive-side relay SMRB, the negative-side relay SMRG, the precharge relay SMRP, the relay DCRNN, the relay DCRNG, the relay DCRNB, the relay DCRN, the relay SSRB, the relay SSRG, the relay DCRB, and the relay DCRG.

The drive device 20 of the embodiment, when driving the open-winding motor 26 as a traveling motor during vehicle travel, is configured such that the positive-side relay SMRB, the negative-side relay SMRG, the relay SSRB, the relay SSRG, and the relay DCRNN are turned on, while the relays DCRB, DCRG, DCRN, DCRNB, and DCRNG are turned off. The open-winding motor 26 is driven by switching control of the six transistors T11 to T16 of the first inverter 24 and the transistors T21 to T26 of the second inverter 25 in accordance with a torque command corresponding to an accelerator opening degree and a vehicle speed V, through star connection driving or delta connection driving.

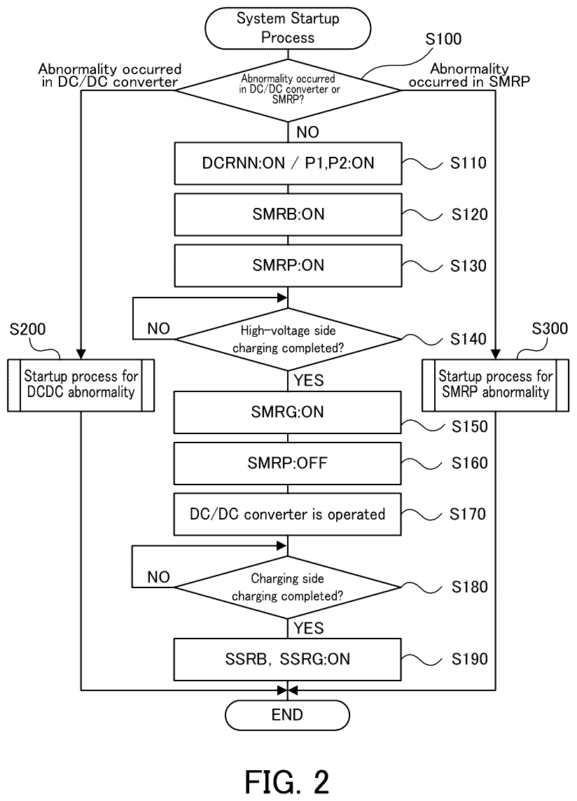

Next, the operation at the time of system startup of the drive device 20 of the embodiment will be described. FIG. 2 is a flowchart illustrating an example of a system startup process executed by the electronic control unit (ECU) 60.

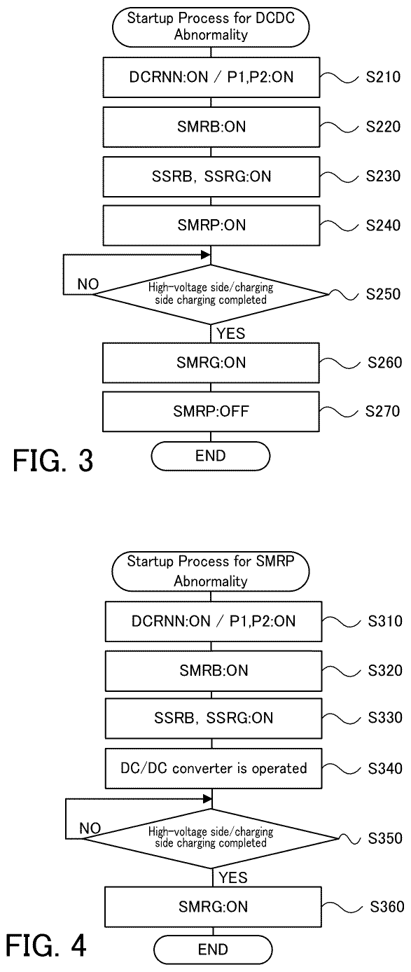

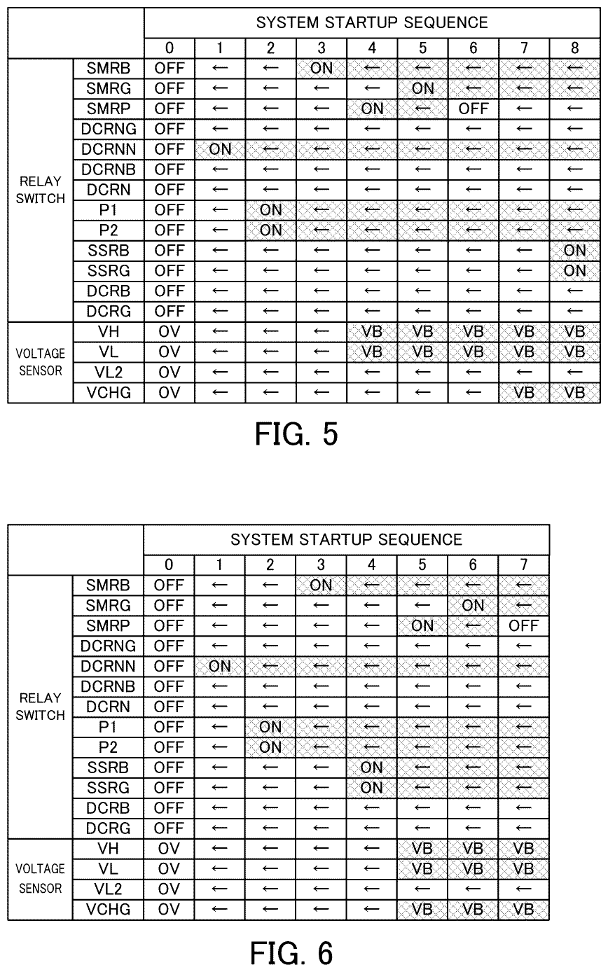

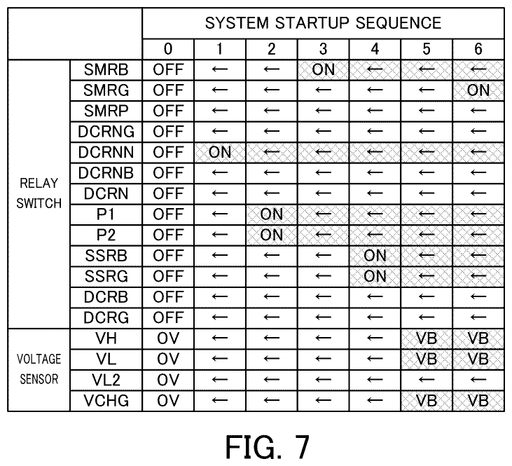

When the system startup process is executed, the electronic control unit (ECU) 60 determines whether an abnormality has occurred in the DC/DC converter 46 or the precharge relay SMRP (step S100). The determination as to whether an abnormality has occurred in the DC/DC converter 46 or the precharge relay SMRP can be made based on the results of a converter abnormality diagnosis process for diagnosing an abnormality in the DC/DC converter 46, and a relay abnormality diagnosis process for diagnosing an abnormality in the precharge relay SMRP. When it is determined that an abnormality has occurred in the DC/DC converter 46, a startup process for the case of a DC/DC abnormality is executed (step S200), and this process is terminated. When it is determined that an abnormality has occurred in the precharge relay SMRP, a startup process for the case of an SMRP abnormality is executed (step S300), and this process is terminated. An example of the startup process for the case of a DC/DC abnormality is shown in FIG. 3, and an example of the startup process for the case of an SMRP abnormality is shown in FIG. 4. The cases where it is determined that both the DC/DC converter 46 and the precharge relay SMRP are normal, where it is determined that an abnormality has occurred in the DC/DC converter 46, and where it is determined that an abnormality has occurred in the precharge relay SMRP will be described in order. FIG. 5 illustrates a system startup sequence when it is determined that both the DC/DC converter 46 and the precharge relay SMRP are normal, FIG. 6 illustrates a system startup sequence when it is determined that an abnormality has occurred in the DC/DC converter 46, and FIG. 7 illustrates a system startup sequence when it is determined that an abnormality has occurred in the precharge relay SMRP.

When it is determined in step S100 that both the DC/DC converter 46 and the precharge relay SMRP are normal, a normal process is executed. First, the relay DCRNN is turned on and the connection switches P1 and P2 are turned on (step S110, sequences 1 and 2 in FIG. 5). That is, the first battery 22a and the second battery 22b of the battery 22 are connected in series, and the voltage VB of the battery 22 is applied to the first inverter 24 and the second inverter 25.

Subsequently, the positive-side relay SMRB of the system main relay is turned on (step S120, sequence 3 in FIG. 5), and the precharge relay SMRP is turned on (step S130, sequence 4 in FIG. 5), and charging of the first smoothing capacitor 32 and the second smoothing capacitor 33 (high-voltage side) is started by the power of the battery 22 in which the first battery 22a and the second battery 22b are connected in series. Then, completion of charging of the first smoothing capacitor 32 and the second smoothing capacitor 33 (high-voltage side) is awaited (step S140).

When charging of the first smoothing capacitor 32 and the second smoothing capacitor 33 (high-voltage side) is completed, the negative-side relay SMRG is turned on (step S150, sequence 5 in FIG. 5), and the precharge relay SMRP is turned off (step S160, sequence 6 in FIG. 5). Then, the DC/DC converter 46 is operated (step S170), and charging of the AC charging smoothing capacitor 41c (on the charging side) is started by the DC/DC converter 46 using the power of the auxiliary battery 48, and completion of charging of the AC charging smoothing capacitor 41c (on the charging side) is awaited (step S180, sequence 7 in FIG. 5). When charging of the AC charging smoothing capacitor 41c (on the charging side) is completed, the relays SSRB and SSRG are turned on (step S190, sequence 8 in FIG. 5), and the system startup is completed.

When it is determined in step S100 that an abnormality has occurred in the DC/DC converter 46, a startup process for the case of a DC/DC abnormality, exemplified in FIG. 3, is executed. In the startup process for the case of a DC/DC abnormality, the electronic control unit (ECU) 60 first turns on the relay DCRNN and also turns on the connection switches P1 and P2 (step S210, sequences 1 and 2 in FIG. 6). Similar to the normal process, the first battery 22a and the second battery 22b of the battery 22 are connected in series, and the voltage VB of the battery 22 is applied to the first inverter 24 and the second inverter 25.

Subsequently, the positive-side relay SMRB of the system main relay is turned on (step S220, sequence 3 in FIG. 6), and the relays SSRB and SSRG are turned on (step S230, sequence 4 in FIG. 6). Then, the precharge relay SMRP is turned on (step S240, sequence 5 in FIG. 6), and charging of the first smoothing capacitor 32, the second smoothing capacitor 33 (high-voltage side), and the AC charging smoothing capacitor 41c (on the charging side) is started by the power of the battery 22 in which the first battery 22a and the second battery 22b are connected in series, and completion of charging of these capacitors is awaited (step S250).

When charging of the respective capacitors is completed, the negative-side relay SMRG is turned on (step S260, sequence 6 in FIG. 6), and the precharge relay SMRP is turned off (step S270, sequence 7 in FIG. 6), thereby completing the system startup.

When it is determined in step S100 that an abnormality has occurred in the precharge relay SMRP, a startup process for the case of an SMRP abnormality, exemplified in FIG. 4, is executed. In the startup process for the case of an SMRP abnormality, the electronic control unit (ECU) 60 first turns on the relay DCRNN and also turns on the connection switches P1 and P2 (step S310, sequences 1 and 2 in FIG. 7). Similar to the normal process, the first battery 22a and the second battery 22b of the battery 22 are connected in series, and the voltage VB of the battery 22 is applied to the first inverter 24 and the second inverter 25.

Subsequently, the positive-side relay SMRB of the system main relay is turned on (step S320, sequence 3 in FIG. 7), and the relays SSRB and SSRG are turned on (step S330, sequence 4 in FIG. 7). Then, the DC/DC converter 46 is operated (step S340), and charging of the AC charging smoothing capacitor 41c (on the charging side), the first smoothing capacitor 32, and the second smoothing capacitor 33 (high-voltage side) is started by the DC/DC converter 46 using the power of the auxiliary battery 48, and completion of charging of these capacitors is awaited (step S350, sequence 5 in FIG. 7).

When charging of the respective capacitors is completed, the negative-side relay SMRG is turned on (step S360, sequence 6 in FIG. 7), thereby completing the system startup.

In the drive device 20 of the embodiment described above, when both the DC/DC converter 46 and the precharge relay SMRP are normal, as a normal process, the relay DCRNN is turned on and the connection switches P1 and P2 are turned on to connect the first battery 22a and the second battery 22b of the battery 22 in series, and to set a state in which the voltage VB of the battery 22 is applied to the first inverter 24 and the second inverter 25. In this state, the positive-side relay SMRB of the system main relay is turned on, and the precharge relay SMRP is turned on to perform charging on the high-voltage side. After that, the negative-side relay SMRG is turned on and the precharge relay SMRP is turned off. Then, the DC/DC converter 46 is operated to charge the AC charging smoothing capacitor 41c, and thereafter the relays SSRB and SSRG are turned on to complete the system startup. Accordingly, the system startup can be performed while charging the first smoothing capacitor 32, the second smoothing capacitor 33, and the AC charging smoothing capacitor 41c.

On the other hand, when an abnormality occurs in the DC/DC converter 46, the relay DCRNN is turned on and the connection switches P1 and P2 are turned on, the positive-side relay SMRB of the system main relay is turned on, and the relays SSRB and SSRG are turned on. Then, the precharge relay SMRP is turned on to charge the first smoothing capacitor 32, the second smoothing capacitor 33 (high-voltage side), and the AC charging smoothing capacitor 41c (on the charging side). After that, the negative-side relay SMRG is turned on and the precharge relay SMRP is turned off to complete the system startup. Accordingly, even when an abnormality occurs in the DC/DC converter 46, the system startup can be performed while charging the first smoothing capacitor 32, the second smoothing capacitor 33, and the AC charging smoothing capacitor 41c.

Further, when an abnormality occurs in the precharge relay SMRP, the relay DCRNN is turned on and the connection switches P1 and P2 are turned on, the positive-side relay SMRB of the system main relay is turned on, and the relays SSRB and SSRG are turned on. Then, the DC/DC converter 46 is operated to charge the AC charging smoothing capacitor 41c, the first smoothing capacitor 32, and the second smoothing capacitor 33. After that, the negative-side relay SMRG is turned on to complete the system startup. Accordingly, even when an abnormality occurs in the precharge relay SMRP, the system startup can be performed while charging the first smoothing capacitor 32, the second smoothing capacitor 33, and the AC charging smoothing capacitor 41c.

In the drive device 20 of the embodiment, the battery 22 includes the first battery 22a and the second battery 22b, and the main power circuit 30 is configured such that the first battery 22a and the second battery 22b can be connected in series or in parallel. However, the configuration may instead include only a single battery.

In the first drive device or the second drive device of the present disclosure, a line connection switch may be provided on the positive-side line of the high-voltage power line between the first inverter and the second inverter, and the controller may be configured to turn on the line connection switch before turning on the positive-side relay at the time of system startup. In this case, the power storage device includes the first battery and the second battery, and is provided with a plurality of relays. By turning on and off the plurality of relays, the series connection of the first battery and the second battery and the parallel connection of the first battery and the second battery can be switched by a series-parallel switching circuit. The controller may be configured to turn on and off the plurality of relays of the series-parallel switching circuit such that the first battery and the second battery are connected in series before turning on the positive-side relay at the time of system startup. That is, the system is started with the first battery and the second battery connected in series. Further, in this case, the series-parallel switching circuit may include: a series connection line connecting the negative terminal of the first battery and the positive terminal of the second battery; a series connection relay mounted on the series connection line; the positive-side power line connected to the positive terminal of the first battery; the negative-side power line connected to the negative terminal of the second battery; the first inverter; the second inverter; the open-winding motor; the system main relay; a first parallel connection line connecting the side of the first battery of the series connection line, upstream of the series connection relay, and the negative-side power line; a first parallel connection relay mounted on the first parallel connection line; a second parallel connection line connecting the positive terminal of the second battery and a connection point of the second inverter on the positive-side power line; and a second parallel connection relay and a third parallel connection relay mounted in order from the second battery side on the second parallel connection line.

The correspondence between the main elements of the embodiment and the main elements of the disclosure described in the Summary section will be described. In the embodiment, the battery 22 corresponds to “the power storage device,” the open-winding motor 26 corresponds to “the open-winding motor,” the first inverter 24 corresponds to “the first inverter,” the second inverter 25 corresponds to “the second inverter,” the first smoothing capacitor 32 and the second smoothing capacitor 33 correspond to “the high-voltage-side smoothing capacitor,” the positive-side relay SMRB corresponds to “the positive-side relay,” the negative-side relay SMRG corresponds to “the negative-side relay,” the precharge relay SMRP corresponds to “the precharge relay,” the system main relay corresponds to “the system main relay,” the auxiliary battery 48 corresponds to “the auxiliary battery,” the DC/DC converter 46 corresponds to “the DC/DC converter,” the relays SSRB and SSRG correspond to “the branch relay,” the AC charging smoothing capacitor 41c corresponds to “the branch-side smoothing capacitor,” and the electronic control unit 60 corresponds to “the controller”.

It should be noted that the correspondence between the main elements of the embodiment and the main elements of the disclosure described in the Summary section is provided solely as an example to specifically illustrate one possible mode of implementing the disclosure. Therefore, the elements of the disclosure described in the Summary section should not be construed as being limited by the embodiment. In other words, the interpretation of the disclosure should be based on the description in the Summary section, and the embodiment merely represents a specific example of the disclosure described therein.

While the present disclosure has been described above with reference to the embodiment as an example of one mode of implementation, the present disclosure is not limited to the embodiment. Various modifications and variations may be made to the embodiment without departing from the scope and spirit of the present disclosure.

### INDUSTRIAL APPLICABILITY

The present disclosure is applicable to industries involved in the manufacture of drive devices and the like.

What is claimed is:

1. A drive device comprising:
a power storage device;
an open-winding motor;
a first inverter connected to a high-voltage power line connected to the power storage device and to one end of a three-phase coil of the open-winding motor;
a second inverter connected to the high-voltage power line and to the other end of the three-phase coil of the open-winding motor;
a high-voltage-side smoothing capacitor mounted on the high-voltage power line;
a system main relay comprising a positive-side relay mounted on a positive line of the high-voltage power line on a side of the power storage device relative to the smoothing capacitor, a negative-side relay mounted on a negative line of the high-voltage power line, and a precharge circuit formed by a precharge relay connected in parallel with the negative-side relay and a limiting resistor connected in series with the precharge relay;
an auxiliary battery;
a DC/DC converter connected to a branch power line connected between the positive line of the high-voltage power line between the power storage device and the system main relay and the negative line of the high-voltage power line between the system main relay and the first inverter, and further connected to a low-voltage power line connected to the auxiliary battery, the DC/DC converter being configured to exchange power with voltage conversion between the branch power line and the low-voltage power line;
a branch relay mounted on the branch power line;
a branch-side smoothing capacitor mounted on the branch power line between the branch relay and the DC/DC converter; and
a controller configured to control the first inverter, the second inverter, and the DC/DC converter, and to drive-control the system main relay and the branch relay,
wherein the controller is configured to:
in a normal condition, turn on the positive-side relay of the system main relay and the precharge relay to charge the high-voltage-side smoothing capacitor, then turn on the negative-side relay, and further charge the branch-side smoothing capacitor by the DC/DC converter and then turn on the branch relay to start the system; and
when an abnormality occurs in the DC/DC converter, turn on the positive-side relay of the system main relay and the branch relay, and also turn on the precharge relay to charge the high-voltage-side smoothing capacitor and the branch-side smoothing capacitor, and then turn on the negative-side relay to start the system.

2. The drive device according to claim 1, wherein the controller is configured to:
in a normal condition, turn on the positive-side relay and then turn on the precharge relay to charge the high-voltage-side smoothing capacitor, after completion of charging of the high-voltage-side smoothing capacitor turn on the negative-side relay and then turn off the precharge relay, thereafter charge the branch-side smoothing capacitor by the DC/DC converter and then turn on the branch relay to start the system; and
when an abnormality occurs in the DC/DC converter, turn on the positive-side relay and the branch relay, then turn on the precharge relay to charge the high-voltage-side smoothing capacitor and the branch-side smoothing capacitor, after completion of charging of the high-voltage-side smoothing capacitor and the branch-side smoothing capacitor turn on the negative-side relay and then turn off the precharge relay to start the system.

3. The drive device according to claim 1, further comprising a line connection switch mounted on the positive line of the high-voltage power line between the first inverter and the second inverter,
wherein the controller is configured, upon starting the system, to turn on the line connection switch before turning on the positive-side relay.

4. The drive device according to claim 3, wherein the power storage device includes a first battery and a second battery,
the drive device further comprising a series-parallel switching circuit including a plurality of relays, the plurality of relays being switchable to connect the first battery and the second battery in series or in parallel,
wherein the controller is configured, upon starting the system, to turn on and off the plurality of relays of the series-parallel switching circuit such that the first battery and the second battery are connected in series before turning on the positive-side relay.

5. The drive device according to claim 4, wherein the series-parallel switching circuit comprises:
a series connection line connecting a negative-side terminal of the first battery and a positive-side terminal of the second battery;
a series connection relay mounted on the series connection line;
the positive-side power line connected to a positive terminal of the first battery;
the negative-side power line connected to a negative terminal of the second battery;
the first inverter;
the second inverter;
the open-winding motor;
the system main relay;
a first parallel connection line connecting the first battery side of the series connection relay on the series connection line and the negative-side power line;
a first parallel connection relay mounted on the first parallel connection line;
a second parallel connection line connecting the positive terminal of the second battery and a connection point of the second inverter on the positive-side power line; and
a second parallel connection relay and a third parallel connection relay sequentially mounted on the second parallel connection line from the side of the second battery.

6. A drive device comprising:
a power storage device;
an open-winding motor;
a first inverter connected to a high-voltage power line connected to the power storage device and to one end of a three-phase coil of the open-winding motor;
a second inverter connected to the high-voltage power line and to the other end of the three-phase coil of the open-winding motor;
a high-voltage-side smoothing capacitor mounted on the high-voltage power line;
a system main relay comprising a positive-side relay mounted on a positive line of the high-voltage power line on a side of the power storage device relative to the smoothing capacitor, a negative-side relay mounted on a negative line of the high-voltage power line, and a precharge circuit formed by a precharge relay connected in parallel with the negative-side relay and a limiting resistor connected in series with the precharge relay;
an auxiliary battery;
a DC/DC converter connected to a branch power line connected between the positive line of the high-voltage power line between the power storage device and the system main relay and the negative line of the high-voltage power line between the system main relay and the first inverter, and further connected to a low-voltage power line connected to the auxiliary battery, the DC/DC converter being configured to exchange power with voltage conversion between the branch power line and the low-voltage power line;
a branch relay mounted on the branch power line;
a branch-side smoothing capacitor mounted on the branch power line between the branch relay and the DC/DC converter; and
a controller configured to control the first inverter, the second inverter, and the DC/DC converter, and to drive-control the system main relay and the branch relay,
wherein the controller is configured to:
in a normal condition, turn on the positive-side relay of the system main relay and the precharge relay to charge the high-voltage-side smoothing capacitor, then turn on the negative-side relay, and further charge the branch-side smoothing capacitor by the DC/DC converter and then turn on the branch relay to start the system; and
when an abnormality occurs in the precharge relay, turn on the positive-side relay of the system main relay and the branch relay, and further charge the high-voltage-side smoothing capacitor and the branch-side smoothing capacitor by the DC/DC converter, then turn on the negative-side relay to start the system.

7. The drive device according to claim 6, wherein the controller is configured to:
in a normal condition, turn on the positive-side relay and then turn on the precharge relay to charge the high-voltage-side smoothing capacitor, after completion of charging of the high-voltage-side smoothing capacitor turn on the negative-side relay and then turn off the precharge relay, thereafter charge the branch-side smoothing capacitor by the DC/DC converter and then turn on the branch relay to start the system; and
when an abnormality occurs in the precharge relay, turn on the positive-side relay and the branch relay, then charge the high-voltage-side smoothing capacitor and the branch-side smoothing capacitor by the DC/DC converter, after completion of charging of the high-voltage-side smoothing capacitor and the branch-side smoothing capacitor turn on the negative-side relay to start the system.

8. The drive device according to claim 6, further comprising a line connection switch mounted on the positive line of the high-voltage power line between the first inverter and the second inverter,
wherein the controller is configured, upon starting the system, to turn on the line connection switch before turning on the positive-side relay.

9. The drive device according to claim 8, wherein the power storage device includes a first battery and a second battery,
the drive device further comprising a series-parallel switching circuit including a plurality of relays, the plurality of relays being switchable to connect the first battery and the second battery in series or in parallel,
wherein the controller is configured, upon starting the system, to turn on and off the plurality of relays of the series-parallel switching circuit such that the first battery and the second battery are connected in series before turning on the positive-side relay.

10. The drive device according to claim 9, wherein the series-parallel switching circuit comprises:
a series connection line connecting a negative-side terminal of the first battery and a positive-side terminal of the second battery;
a series connection relay mounted on the series connection line;
the positive-side power line connected to a positive terminal of the first battery;
the negative-side power line connected to a negative terminal of the second battery;
the first inverter;
the second inverter;
the open-winding motor;
the system main relay;
a first parallel connection line connecting the first battery side of the series connection relay on the series connection line and the negative-side power line;
a first parallel connection relay mounted on the first parallel connection line;
a second parallel connection line connecting the positive terminal of the second battery and a connection point of the second inverter on the positive-side power line; and
a second parallel connection relay and a third parallel connection relay sequentially mounted on the second parallel connection line from the side of the second battery.
